(19) United States
(12) Patent Application Publication
(10) Pub. No.: US 2008/0212668 A1
(43) Pub. Date: Sep. 4, 2008

(54) Data Transmission Method, Transmitter and Receiver Therefor

(75) Inventors: Dieter Thoss, Schwieberdingen (DE); Jens Boettcher, Schwieberdingen (DE); Andreas Kneer, Wendlingen (DE); Michael Besemer, Esslingen (DE)

Correspondence Address: KENYON & KENYON LLP, ONE BROADWAY, NEW YORK, NY, 10004, US

(73) Assignee: ROBERT BOSCH GMBH, Stuttgart (DE)

(21) Appl. No.: 11/885,722

(22) PCT Filed: Mar. 2, 2006
(86) PCT No.: PCT/EP2006/060380

§ 371 Date: Sep. 4, 2007

(30) Foreign Application Priority Data
Mar. 3, 2005 (DE) 10 2005 009 735.9

(51) Int. Cl. H03K 7/08

(52) U.S. Cl. 375/238

(57) ABSTRACT

A method for serial data transmission from a transmitter to a receiver has the following steps:
a) establishing at least one digital data word which is representative of a data value to be transmitted;
b) establishing a pulse duration which is proportional to a non-negative integer represented by the data word plus a constant positive allowance;
c) transmitting a pulse (IH, IM, IL) having the established pulse duration from the transmitter to the receiver; and
d) detecting the pulse duration at the receiver and reconstructing the data word.

### BACKGROUND INFORMATION

The present invention relates to a method for serial data transmission from a transmitter to a receiver, as well as transmitters and receivers which are capable of performing the method.

More and more digital data processing circuits are used in modern motor vehicles, in particular for detecting and controlling or regulating operating parameters of the internal combustion engine of a motor vehicle. Digital data lines which run in proximity to the internal combustion engine are subjected to strong electromagnetic interference due to the operation of the latter, in particular due to the spark plugs. This problem is particularly serious when a parameter, such as the combustion chamber pressure, is to be detected directly at the combustion chamber at high bandwidth. Standards for digital data transmission in motor vehicles, such as CAN, are known, but their implementation is still rather costly. Transmitting a measured variable to be detected in an environment heavily loaded with electromagnetic interference initially as an analog variable and performing digitization and digital processing at a greater distance from the interference source would be conceivable, but such a procedure is inherently imprecise and allows higher transmission rates only when short measuring times of the transmitted analog signal level and therefore in turn increased sensitivity to interference are accepted.

A further known method for transmitting data, which may be implemented cost-effectively and is less sensitive to electromagnetic interference, is pulse duration modulation. In this method, a pulse duration proportional to the binary numerical value of the data word is established for a digital data word to be transmitted, a pulse having the established duration is transmitted from a transmitter to a receiver, and the data word is reconstructed on the basis of the pulse duration detected by the receiver.

This known method has two essential disadvantages. Firstly, it is not possible to transmit a pulse representing the numerical value 0, since its duration would be 0. In addition, the time required for transmitting a data value increases exponentially with the resolution (i.e., the bit count) of the data value. Specifically, the duration of the shortest pulse which may be transmitted from the transmitter to the receiver is established by the structure of the transmitter, the receiver, and a transmission medium connecting the two, so that increasing-the precision by one bit causes a doubling of the pulse duration in each case.

### SUMMARY OF THE INVENTION

A method for data transmission through pulse duration modulation and a transmitter capable thereof, which also allow the transmission of the value 0 by establishing the pulse duration in each case proportionally to a nonnegative integer representing the data word to be transmitted plus a constant positive allowance, are provided by the present invention as defined in claims 1 and 12. The duration of the pulse to be transmitted upon transmission of the value 0 thus solely corresponds to the numerical value of the allowance, and a detectable pulse of non-vanishing duration is incident at the receiver.

The allowance preferably contains a first term which corresponds to a number between 0 and 1; preferably 0.5. If this term is simply neglected when reconstructing the data word at the receiver, the data word is nonetheless correctly obtained again.

Preferably, the pulse to be transmitted is obtained by a digital-time conversion of an expanded data word whose bits include the original data word to be transmitted and at least one bit representative of the first term, whose significance is lower than that of the bits of the established data word.

Alternatively or additionally, the allowance preferably also contains a term whose numerical value corresponds to the greatest integer which may be represented by the original data word plus 1. It is thus ensured that the minimum duration of each transmitted pulse at least corresponds to this greatest integer which may be represented, and extremely short pulses, which require a high bandwidth of the transmission medium for their transmission, are avoided.

Such a pulse is easily obtainable by a digital-time conversion of an expanded data word whose bits include the original data word to be transmitted and, in addition, a bit having the value 1, whose significance is higher than that of the bits of the original data word.

Very rapid transmission even of data values having very high resolution may be achieved by first dividing the bits of the digital data value to be transmitted into multiple data words and performing the transmission through pulse width modulation as described above in succession for each of the data words thus obtained. This is only possible because the method according to the present invention also allows the transmission of a data word having the value 0. A receiver capable of this is the subject matter of claim 16.

In order to save time during the transmission of the multiple data words in succession, it is expedient to transmit them directly in succession having alternating levels.

A time window of predefined length may be provided for each data value, in which the data value, divided into an odd number of data words, is transmitted. It results from this that a filler signal is transmitted at the end of each time window, whose level is identical to the pulse used for transmitting the second data word, so that the identical level may be used in each case for the first data words of different data values.

During transmission of a data value divided into an even number of data words in a time window of predefined length, the first pulses of successive data values—each of which corresponds to their first data words—are each transmitted using alternating levels.

Because of the use of a time window of fixed duration for each data value, the starting instants of the first pulse of each data value have a fixed time interval corresponding to the duration of the time window. A receiver is therefore capable, on the basis of the periodic return of the beginning of the first pulse, of recognizing them and thus synchronizing itself.

### BRIEF DESCRIPTION OF THE DRAWING

Further features and advantages of the present invention result from the following description of exemplary embodiments with reference to the attached figures.

FIG. 1 shows a block diagram of a transmitter according to the present invention;

FIG. 2 shows an exemplary curve of a transmission signal of the transmitter from FIG. 1;

FIG. 3 shows a block diagram of a receiver complementary to the transmitter of FIG. 1;

FIG. 4 shows a block diagram of a transmitter according to a second embodiment;

FIG. 5 shows an exemplary curve of a transmission signal according to a second embodiment of the method;

FIG. 6 shows a block diagram of a receiver complementary to the transmitter of FIG. 4;

FIG. 7 shows an exemplary curve of a transmission signal according to a variation of the method;

FIG. 8 shows a block diagram of a transmitter according to a third embodiment of the present invention;

FIG. 9 shows an exemplary curve of a transmission signal of the transmitter from FIG. 8; and

FIG. 10 shows an exemplary curve of a transmission signal according to a further variation of the method.

### DESCRIPTION OF THE INVENTION

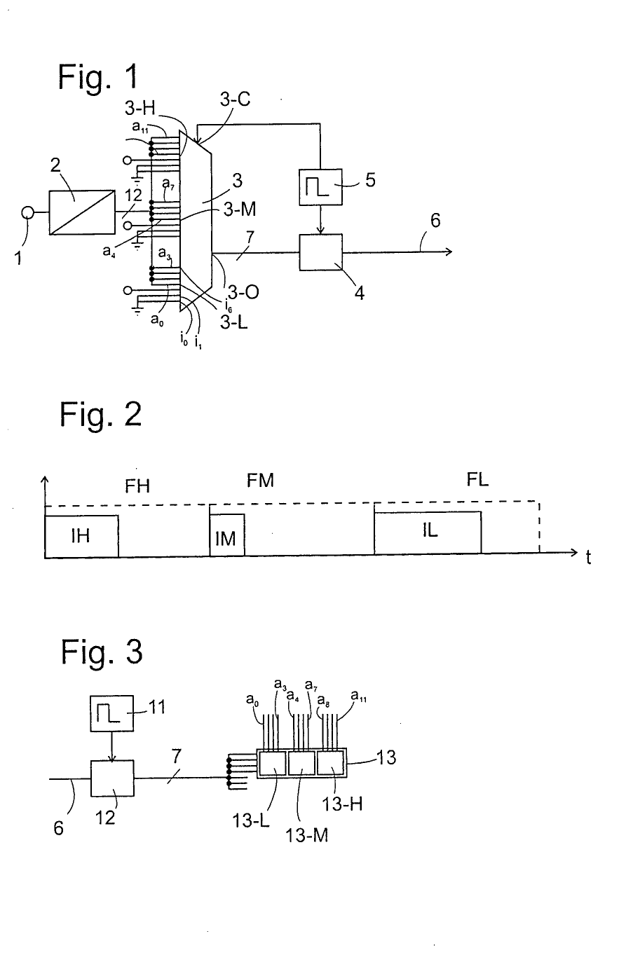

The transmitter schematically shown in FIG. 1 includes a sensor, a pressure sensor 1 in the present case, which is attached to a combustion chamber of a motor vehicle internal combustion engine to detect its internal pressure, and an analog-digital converter 2, which converts an output signal of pressure sensor 1 into a digital data value having a resolution of 12 bits. The bits are identified by a₀, a₁, . . . , a₁₁ in the sequence of increasing significance. A multiplexer 3 has three inputs 3-H, 3-M, 3-L and an output 3-O of 7 bits width each. The four most significant bits of each of three inputs 3-H, 3-M, 3-L are supplied with bits a₁₁, a₁₀ through a₈, a₇ through a₄, or a₃ through a₀ from converter 2. The bit of next-lower significance at each of the three inputs is permanently supplied with the level logical 1, the two bits of lowest significance with the logical 0. The individual bits, identified by i₀ through i₆ in the sequence of increasing significance, of the three inputs are supplied as shown in summary in the following Table 1.

TABLE 1

| | i₆ | i₅ | i₄ | i₃ | i₂ | i₁ | i₀ |
|---|---|---|---|---|---|---|---|
| 3-H | a₁₁ | a₁₀ | a₉ | a₈ | 1 | 0 | 0 |
| 3-M | a₇ | a₆ | a₅ | a₄ | 1 | 0 | 0 |
| 3-L | a₃ | a₂ | a₁ | a₀ | 1 | 0 | 0 |

If the numerical value of the least-significant input bit of converter 4 supplied with a bit from converter 2 is assumed to be 1, three bits i₂, i₁, and i₀ represent an allowance of 0.5.

A 2-bit control signal applied to a control input 3-C of multiplexer 3 determines which of its inputs 3-H, 3-M, 3-L, and 3-N is connected through to output 3-O. A digital-time converter 4, which is used for the purpose of providing output pulses whose duration is linearly proportional to the numerical value represented by the particular 7-bit word output by multiplexer 3, is connected to output 3-O. For this purpose, digital-time converter 4 includes a 7-bit counter, which counts cycles of a clock generator 5, and a comparator, which compares the content of the counter to the data value input into converter 4 and outputs a positive output level on a transmission line 6 as long as the count is less than the input data value and goes to 0 when the count is greater. Clock generator 5 also provides the 2-bit control signal at control input 3-C, which changes its value every 128 cycles. The change of the value of the control signal is synchronized in each case to the overflow of the counter of converter 4, which repeats every 128 cycles.

FIG. 2 shows an example of the transmission signal output at the output of digital-time converter 4 over the course of time t. Time windows FH, FM, FL of 128 cycle periods each in duration are each symbolized by dashed rectangles. Each of time windows FH, FM, FL contains one pulse IH, IM, IL, whose duration is equal to the cycle periods, multiplied by the 7-bit binary number applied to input 3-H, 3-M, or 3-L of multiplexer 3. For example, if a period of clock generator 5 of 50 ns (corresponding to a clock frequency of 20 MHz) is assumed, three times 128×50 ns=19.2 μs are required to transmit a 12-bit output value of analog-digital converter 2. For a typical pulse duration modulation transmission of the same data value, 212×50 ns=4096×50 ns=204.8 μs, i.e., approximately 30 times as long, would be required.

A receiver for the signal shown in FIG. 2 is illustrated in FIG. 3. It includes a clock generator 11, whose clock frequency must correspond to that of clock generator 5 sufficiently precisely to avoid errors when reproducing the output of analog-digital converter 2 on the receiver side, the requirements for the precision of the period correspondence not being too high, however, as will become clear in the following. A time-digital converter 12 receives the pulses provided by converter 4 of the transmitter and, in addition, the clock signal from clock generator 11 and counts the cycle periods during the duration of a pulse in each case. The count result is a binary value of 7 bit width. The four most significant bits of the count result are accommodated in a shift register 13 having three memory locations 13H, 13M, 13L of 4 bits each. The three least significant bits of the count result are discarded. The count result of converter 12 may thus differ from the corresponding input value of converter 4 in these 3 bits without transmission errors occurring, so that deviations between the cycle periods of clock generators 5 and 11 which result in deviations only in these three bits may be permitted.

In each case after the reception of 3 pulses by time-digital converter 12, memory locations 13H, 13M, 13L of shift register 13 contain bits a₁₁ through a₈, a₇ through as, or a₃ through a₀ of the same output value of analog-digital converter 2. By simultaneously reading out all 3 memory locations, this 12-bit data value is reproduced on the receiver side.

In order to allow the receiver to differentiate between the different significant pulses of the same data value, an empty time window may be transmitted in each case between time windows FL and FH belonging to successive data values, the receiver reacting to the arrival of this empty time window by erasing shift register 13. It is thus ensured that the content read out of shift register 13 after receiving free pulses in each case is associated with the same data value. The empty time window may be transmitted after each individual data value or also only after a larger number of data values.

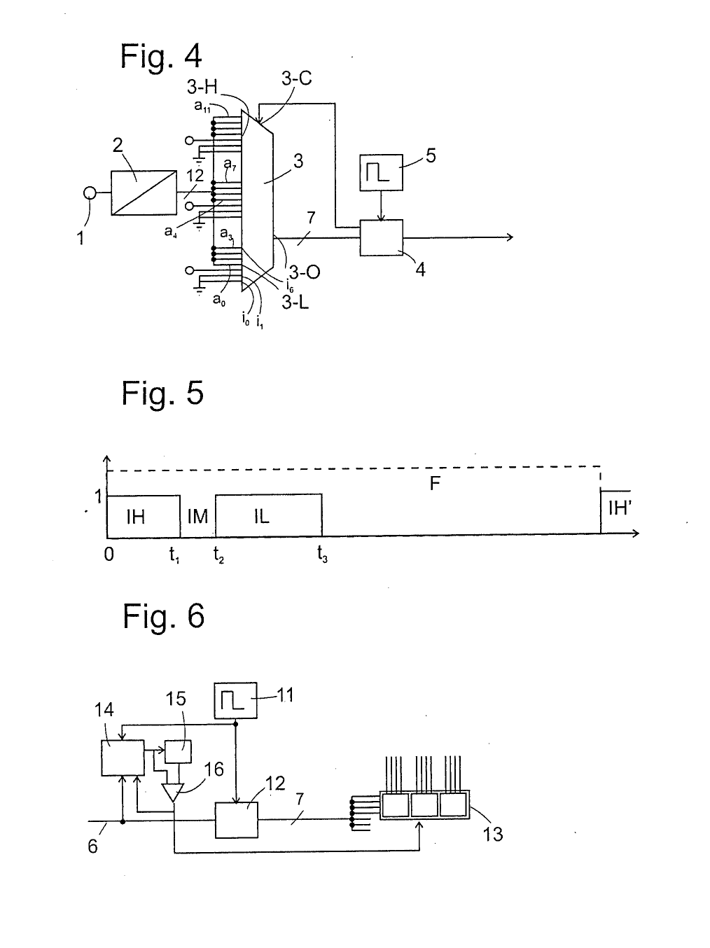

FIG. 4 shows a second embodiment of a transmitter according to the present invention. It differs from the embodiment of FIG. 1 in that the 2-bit control signal supplied to control input 3-C of multiplexer 3 is produced by digital-time converter 4 and always changes its value when the output of a pulse has ended, and the pulses of a data value in direct succession are produced having alternating signal levels.

FIG. 5 shows an example of the time curve of the output signal of the transmitter from FIG. 4 during the transmission of an output data value of analog-digital converter 2. The transmission of pulse IH corresponding to the most significant 4 bits all through a₈ of this output data value lasts from time origin 0 to t₁; pulse IH has the level logical 1. At instant t₁, the control signal at input 3-C changes its value, so that multiplexer 3 outputs 7 bits a₇, a₆, a₅, a₄, 1, 0, 0 and converter 4 begins to convert this value into pulse IM, now having the level logical 0. Pulse IM ends at instant t₂, the control signal at input 3-C changes again, and the bits (a₃, a₂, a₁, a₀, 1, 0, 0) are converted by converter 4 into pulse IL having the level logical 1. At the end of this pulse at instant t₃, the transmission of the entire output data value of analog-digital converter 2 is ended, and the output signal of converter 4 remains at the value 0 during the remaining duration of time window F provided for the transmission of this value.

The duration of time window F does not need to be greater than 3×27=384 cycle periods of clock generator 5, since the maximum possible length of pulses IH, IM, IL is binary “1111100”=124 cycle periods in each case, and as a result at least 12 cycle periods having signal level logical 0 remain at the end of time window F, which separate pulse IL from pulse IH′ of the following time window.

In order to be able to analyze the pulses correctly at the receiver, it must be capable of identifying the particular first pulse from a group which jointly codes a data value, i.e., pulse IH here. For this purpose, the receiver schematically shown in FIG. 6 is additionally provided with a counter 14, which receives the input signal from transmission line 6 and the clock signal from clock generator 1 and, triggered in each case by a rising flank of the input signal, counts the number of cycles to the second following rising flank of the input signal. A register 15 is connected to the output of counter 14 which stores the count output by counter 14 in each case after completion of a counting cycle. Two inputs of a comparator 16 are connected to the outputs of counter 14 and register 15 respectively, so that comparator 16 compares the last and the next-to-last count result in each case. Since the rising flanks at the beginning of pulses IH of successive time windows have a fixed time interval of 3×128 cycle periods, the numerical values applied to the inputs of comparator 16 are always identical when the rising flank which triggers counter 14 is that of pulse IH. If the counter has been triggered by the rising flank of pulse IL, however, a correspondence may occur coincidentally at comparator 16; but as soon as a non-correspondence has been established, i.e., the last received rising flank must belong to pulse IL, comparator 16 provides an output signal to counter 14 and shift register 13 which resets counter 14 and erases the contents of shift register 13. If counter 14 is triggered again by the following rising flank of the input signal, this may only be the rising flank of a pulse IH, and the synchronization is established.

A synchronization is also achievable in the same way if three successive pulses do not code a data value, as assumed above, but rather a larger odd number of pulses; in the latter case, multiple reset procedures may merely be required before the synchronization is established.

The data rate achievable using this embodiment is higher than that in the transmission method explained with reference to FIG. 2. The required length of time window F does correspond to the sum of the lengths of time windows FH, FM, FL from FIG. 2, but no empty time window is required for synchronization here.

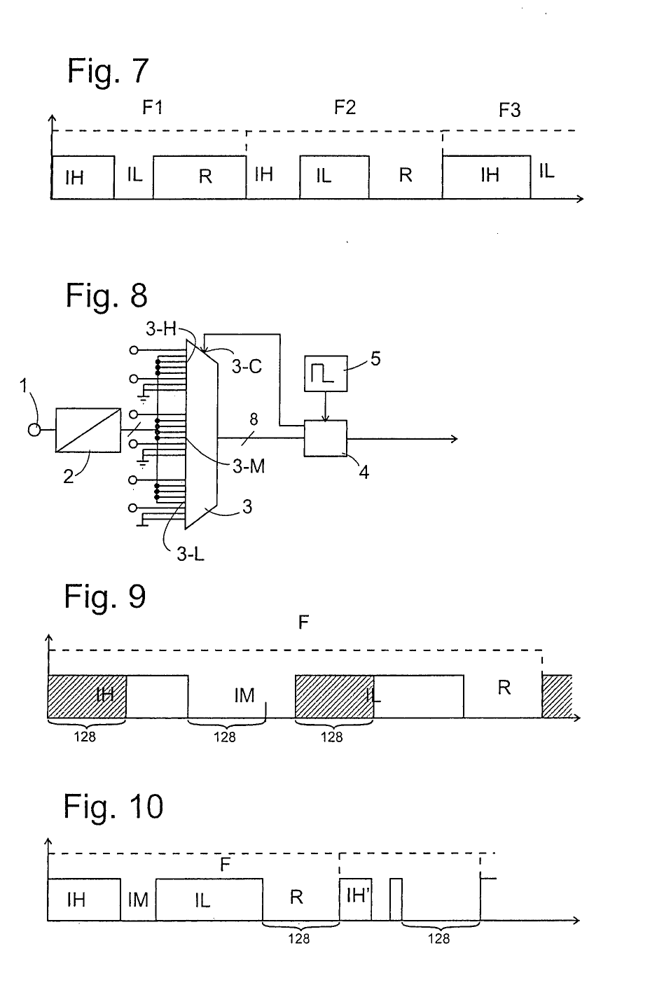

Instead of breaking down a data value to be transmitted into three data words, each of which is to be converted into a pulse, breaking it down into an even number of data words is also possible. FIG. 7 shows the time curve of a transmission signal resulting for the case of breaking the data value down into two data words, which are converted into pulses IH and IL. Each of three time windows F1, F2, F3 shown contains a pulse IH, whose length represents the more significant of the two data words, a pulse IL, whose level is different from that of pulse IH, and which represents the less significant data word, and a filler pulse R, which fills up the remaining time of the window and has the same level as pulse IH. In order to be able to differentiate filler pulse R of one time window from pulse IH of the following time window, the levels of identical pulses in successive time windows are different in each case.

FIG. 8 is a block diagram of a third embodiment of a transmitter according to the present invention. Sensor 1, analog-digital converter 2, and clock generator 5 are the same as those described with reference to FIG. 1 and will not be explained again. Multiplexer 3 in FIG. 8 differs from that of FIG. 1 in that its inputs 3-H, 3-M, 3-L are each 8 bits wide, the occupancy of bits i₀ through i₇ of the three inputs being summarized in the following Table 2.

TABLE 2

| | i₇ | i₆ | i₅ | i₄ | i₃ | i₂ | i₁ | i₀ |
|---|---|---|---|---|---|---|---|---|
| 3-H | 1 | a₁₁ | a₁₀ | a₉ | a₈ | 1 | 0 | 0 |
| 3-M | 1 | a₇ | a₆ | a₅ | a₄ | 1 | 0 | 0 |
| 3-L | 1 | a₃ | a₂ | a₁ | a₀ | 1 | 0 | 0 |

Digital-time converter 4 thus receives data words of 8 bits wide from multiplexer 3, whose value may be between binary 10000100=132 and binary 11111100=252, so that the length of the pulses output by converter 4 is between 132 and 252 cycle periods in each case. The production of pulses of fewer cycle periods in duration, which are possibly strongly damped by transmission line 6 between transmitter and receiver and therefore may be analyzed incorrectly at the receiver, is avoided in this way.

FIG. 9 shows the resulting curve of the transmission signal: each block IH, IM, IL has a component having a fixed length of 128 periods and a variable component, whose length represents the actual information to be transmitted.

A receiver capable of processing the transmission signal of FIG. 9 essentially has the structure shown in FIG. 6; only the width of the output of time-digital converter 12 is increased from 7 to 8, the bit having the highest significance, like the three least significant bits of this output, not being attached to shift register 13, because the memory cells are also only four bits wide here.

In all exemplary embodiments considered up to this point, width-modulated pulses IH, IM, IL have been transmitted in a time window F of fixed duration. It is possible to increase the data rate by using time windows without fixed duration, as shown in FIG. 10. Three pulses IH, IM, IL of a time window F which code an output value of analog-digital converter 2 are followed here by a filler pulse R of a fixed length which is greater than the maximum possible length of each of pulses IH, IM, IL, i.e., 128 cycle periods in the present case, for example. Because of its great length, the filler pulse is easily recognizable as such at the receiver, so that synchronizing the transmitter to first pulse ICH of each window F does not cause any difficulties. Under the assumption that pulses IH, IM, IL assume every possible length with equal probability, it results in the present case that the durations may be between 4 and 124 cycle periods, an expected value for their length is 64 cycle periods, and thus an expected value for the length of entire window F is 3*64+128=320 cycle periods, in contrast to a minimum length of window F of 384 cycle periods in the case of FIG. 5.

1-17. (canceled)

18. A method for serial data transmission from a transmitter to a receiver, comprising:
a) establishing at least one digital data word which is representative of a data value to be transmitted;
b) establishing a pulse duration which is proportional to a non-negative integer represented by the data word plus a constant positive allowance;
c) transmitting a pulse having the established pulse duration from the transmitter to the receiver; and
d) detecting the pulse duration at the receiver and reconstructing the data word.

19. The method as recited in claim 18, wherein the allowance contains a first term which corresponds to a number between 0 and 1.

20. The method as recited in claim 19, wherein the first term corresponds to 0.5.

21. The method as recited in claim 19, wherein the pulse is obtained by a digital-time conversion of an expanded data word, which includes the data word established in step a) and at least one bit representative of the first term as a bit of lower significance than bits of the established data word.

22. The method as recited in claim 18, wherein the allowance contains a term which corresponds to a greatest integer which can be represented by the data word established in step a) plus 1.

23. The method as recited in claim 22, wherein the pulse is obtained by a digital-time conversion of an expanded data word which includes the data word established in step a), and a bit having a value 1 and higher significance than bits of the established data word.

24. The method as recited in claim 18, wherein in step a), bits of the digital data value to be transmitted are divided into multiple data words, and steps b) through d) are performed for each of the data words thus obtained.

25. The method as recited in claim 24, wherein pulses corresponding to the multiple data words are transmitted directly in succession having alternating levels.

26. The method as recited in claim 25, wherein each data value is transmitted in a time window of predefined length, divided into an odd number of data words.

27. The method as recited in claim 25, wherein each data value is transmitted in a time window of predefined length, divided into an even number of data words, and first pulses of successive data values are each transmitted having alternating levels.

28. The method as recited in claim 26, wherein a first pulse of each data value is begun to be transmitted at a beginning of the time window corresponding to the data value, and the receiver recognizes the first pulse of data values transmitted in succession from the periodic return of its beginning.

29. The method as recited in claim 18, wherein the transmitted data value is a pressure measured value, the measured value being a measured value of a combustion chamber pressure in an internal combustion engine.

30. A transmitter comprising:
a digital-time converter for converting a digital data word into a pulse having a duration which is representative of a numerical value of the data word, wherein the duration of the pulse which corresponds to a numerical value 0 is greater than 0.

31. The transmitter as recited in claim 30, wherein the digital-time converter processes an input bit number which is greater than a bit number of a digital data word, input bits which are not supplied with bits of the data word being supplied with a constant value which is 1 for at least one of the bits.

32. The transmitter as recited in claim 31, wherein the input bits of the digital-time converter which are not supplied with the bits of the data word are either more significant or less significant than all bits of the data word.

33. The transmitter as recited in claim 30, further comprising:
a circuit configured to break down a digital data value into multiple data words, each containing a plurality of bits of different significance of the data value.

34. A receiver, comprising:
a time-digital converter to convert a received pulse into a digital data word which represents a data value proportional to a duration of the pulse; and
a chaining circuit to chain predefined bits in succession of data words output by the time-digital converter into a digital data value, at least one bit of least significance of the output data words being neglected by the chaining circuit.

35. The receiver as recited in claim 34, wherein at least one bit of highest significance of the output data words is also neglected by the chaining circuit.
